(19) United States
(12) Patent Application Publication
(10) Pub. No.: US 2025/0185147 A1
(43) Pub. Date: Jun. 5, 2025

(54) EUV Light Source Target Metrology

(71) Applicant: ASML Netherlands B.V., Veldhoven (NL)

(72) Inventors: Yezheng Tao, San Diego, CA (US); Jaden Robert Bankhead, San Diego, CA (US); Sylvi Haendel, San Diego, CA (US); Eric Huang, San Diego, CA (US); Erik Peter Farr, San Diego, CA (US)

(21) Appl. No.: 18/844,195

(22) PCT Filed: Feb. 28, 2023
(86) PCT No.: PCT/EP2023/054911

§ 371 Date: Sep. 5, 2024

Related U.S. Application Data
(60) Provisional application No. 63/322,754, filed on Mar. 23, 2022.

(51) Int. Cl. H05G 2/00

(52) U.S. Cl. CPC H05G 2/0086

(57) ABSTRACT

Disclosed is a system for and method of performing target metrology in an extreme ultraviolet light source in which illumination for a target imaging/detection system is selected to have a center wavelength less than 400 nm. In some embodiments the illumination is additionally selected to have a line width of at least 4 nm. In some embodiments illumination is obtained as a second harmonic of a Ti:sapphire laser or as a harmonic of an Nd:YAG laser.

### CROSS REFERENCE TO RELATED APPLICATIONS

This application claims priority to U.S. Application No. 63/322,754, filed Mar. 23, 2022, titled EUV LIGHT SOURCE TARGET METROLOGY, which is incorporated herein in its entirety by reference.

### TECHNICAL FIELD

The present disclosure relates to light sources which produce extreme ultraviolet light by excitation of a target material, in particular to the measurement, e.g., detection, of a target material in such sources.

### BACKGROUND

Extreme ultraviolet (“EUV”) light, for example, electromagnetic radiation having wavelengths of around 50 nm or less (also sometimes referred to as soft x-rays) and including light at a wavelength of about 13 nm, is used in photolithography processes to produce extremely small features in and on substrates, for example, silicon wafers. The term “light” is used herein to refer to electromagnetic radiation in general regardless of whether the electromagnetic radiation is in the visible part of the spectrum.

Methods for generating EUV light include, but are not limited to, altering the physical state of a target material from an initial state into a plasma state. The target material includes an element, for example, xenon, lithium, or tin, with an emission line in the EUV range. In one such method, often termed laser produced plasma (“LPP”), the required plasma is produced by irradiating a target material, for example, in the form of a droplet, stream, or cluster of target material, with an amplified light beam that can be referred to as a drive laser. For this process, the plasma is typically produced in a sealed vessel, for example, a vacuum chamber, and monitored using various types of metrology equipment.

One objective in the efficient production of EUV light is attaining the proper relative positioning of the conditioning beam and the target. This is also referred to as aligning the conditioning beam and the target. It is generally important to align the target and the conditioning beam to within a few micrometers for efficient and debris-minimized operation of the light source. Thus, considerable effort has been devoted to determining a position of the target relative to the conditioning beam or relative to a frame of reference. See, for example, U.S. Pat. No. 7,372,056, issued May 13, 2008, and titled “LPP EUV Plasma Source Material Target Delivery System,” U.S. Pat. No. 8,158,960, issued Apr. 17, 2012, and titled “Laser Produced Plasma EUV Light Source,” U.S. Pat. No. 9,241,395, issued Jan. 19, 2016, and titled “System and Method for Controlling Droplet Timing in an LPP EUV Light Source,” and U.S. Pat. No. 9,497,840, issued Nov. 15, 2016, and titled “System and Method for Creating and Utilizing Dual Laser Curtains from a Single Laser in an LPP EUV Light Source.”

All patent applications, patents, and printed publications cited herein are incorporated herein by reference in their entireties, except for any definitions, subject matter disclaimers, or disavowals, and except to the extent that the incorporated material is inconsistent with the express disclosure herein, in which case the language in this disclosure controls.

In some EUV sources the target is conditioned with a pulse of radiation that includes a first portion (a “pedestal”) and a second portion (the main pulse or the heating pulse). The first and second portions may be temporally contiguous. In other words, the first portion and the second portion may be part of a single pulse of radiation with no intervening gap or region that lacks radiation between the first portion and the second portion.

The first portion of the pulse of radiation interacts with the target to modify the absorption characteristics of the target. For example, this interaction can modify the absorption characteristics by reducing the density gradient of the target and increasing the volume of the target that interacts with the pulse of radiation at a surface that receives the pulse of radiation, which increases the amount of radiation that the target can absorb. This process is referred to as rarefication, and the pulse which is used to cause rarefication is referred to as a rarefication pulse.

In this manner, the interaction between the target and the first portion of the pulse of radiation conditions the target. The second portion of the pulse of radiation has an energy that is sufficient to convert target material in the target to plasma that emits EUV light. Because the conditioning by the first portion increases the amount of radiation that the target can absorb, the conditioning can result in a greater portion of the target being converted to plasma that emits EUV light. Additionally, the conditioning can reduce the reflectivity of the target, and, therefore, can reduce the amount of back reflections into an optical source that generates the pulse of radiation.

Additionally, the spatial distribution of the target material can be modified to increase the size of the target material in a direction that intersects the amplified light beam before the first portion of the pulse interacts with the target material. For example, the target can be expanded from a droplet into a flat disk with a separate pulse of radiation (a “pre-pulse”) that interacts with the target material. Increasing the size of the target material prior to the interaction with the amplified light beam can increase the portion of the target material that is exposed to the amplified light beam, which can increase the amount of EUV light that is produced for a given amount of target material In other words, the increased target material volume can absorb the pulse of radiation more efficiently and the larger EUV emitting volume can generate an increased amount of EUV light.

While the conditioning pulses help to improve conversion efficiency, altering the density of the target material creates challenges for imaging the target material for metrology purposes. It is in this context that the need for the presently disclosed subject matter arises.

### SUMMARY

The following presents a concise summary of one or more embodiments in order to provide a basic understanding of the embodiments. This summary is not an extensive overview of all contemplated embodiments and is not intended to identify key or critical elements of all embodiments nor set limits on the scope of any or all embodiments. Its sole purpose is to present some concepts of one or more embodiments in a succinct form as a prelude to the more detailed description that is presented later.

According to an aspect of an embodiment there is disclosed a target metrology system for an extreme ultraviolet light source, the target metrology system comprising a light source arranged to emit illuminating laser radiation at a center wavelength less than 400 nm and to illuminate a portion of a target material supply path with the illuminating laser radiation and a radiation receiver arranged to receive the illuminating laser radiation after the illuminating laser radiation has illuminated the portion of the target material supply path.

The radiation receiver may produce an output signal indicative of a position of a target in the portion of the target material supply path. The target metrology system may further comprise a position detection feedback system arranged to receive the output signal of the radiation receiver and adapted to compute a target position or a target trajectory or both based at least in part on the output signal. The radiation receiver may comprise a target imager. The target imager may comprise a camera. The target imager may comprise a CCD array. The target imager may produce a shadowgraph.

The illuminating laser radiation may have a center wavelength of about 266 nm. The light source may comprise a frequency-multiplied Ti:sapphire laser arranged to receive a pump beam and to emit illuminating laser radiation at a center wavelength in a range from about 250 nm to about 450 nm. The light source may comprise a frequency-multiplied Ti:sapphire laser arranged to receive a pump beam and to emit illuminating laser radiation at a center wavelength of about 380 nm.

The light source may further include a diode pumped solid state (DPSS) laser arranged to produce the pump beam, the pump beam having a center wavelength of about 532 nm. The DPSS laser may include an Nd:YAG laser and a frequency multiplier arranged to receive the beam and for producing the pump beam.

The Ti:sapphire laser may comprise a dichroic optical element arranged to receive the pump beam, a Ti:sapphire crystal, and an output coupler. The Ti:sapphire laser may comprise a frequency multiplying element arranged to receive output coupler radiation from the output coupler having a center wavelength of about 760 nm and for multiplying a frequency of the output coupler radiation to produce the illuminating laser radiation at a center wavelength of about 380 nm and with wavelength tuning range from 250 nm to 450 nm. The frequency multiplying element may comprise a nonlinear optical element. The nonlinear optical element comprises a lithium triborate crystal.

The target metrology system may further comprise a fiber beam delivery system arranged and adapted to convey the illuminating laser radiation from the light source to the portion of the target material supply path. The fiber beam delivery system may comprise a multiorder fiber.

The illuminating radiation may be pulsed with a pulse duration in a range of 1 to 10 nanoseconds. The illuminating laser radiation may have a line width not less than 4 nm.

The light source may comprise an Nd:YAG laser and the illuminating laser radiation may be derived as a harmonic of the Nd:YAG laser.

According to another aspect of an embodiment there is disclosed a target metrology method for an extreme ultraviolet light source, the target metrology method comprising illuminating a portion of a target material supply path with illuminating laser radiation having a center wavelength less than 400 nm, receiving as received illumination the illuminating laser radiation after the illuminating laser radiation has illuminated the portion of the target material supply path, and imaging target material present in the portion of the target material supply path on the basis of the received illumination.

Imaging target material may comprise producing an output signal indicative of a position of the target material present in the portion of the target material supply path. The method may further comprise computing a target position or a target trajectory or both based at least in part on the output signal. Imaging target material may comprise using a target imager. The target imager may comprise a camera. The target imager may comprise a CCD array. Imaging target material may comprise producing a shadowgraph.

The illuminating laser radiation may have a center wavelength of about 266 nm. Illuminating the portion of the target material supply path with the illuminating laser radiation having a center wavelength less than 400 nm may be performed at least in part by using a frequency-multiplied Ti:sapphire laser arranged to receive a pump beam and to emit illuminating laser radiation at a center wavelength of about 380 nm and below.

The target metrology method may further comprise pumping the Ti:sapphire laser with a diode pumped solid state (DPSS) laser arranged to produce the pump beam, the pump beam having a center wavelength of about 532 nm. The DPSS laser may include an Nd:YAG laser and a frequency multiplier arranged to receive the beam and for producing the pump beam.

The Ti:sapphire laser may comprise a dichroic optical element arranged to receive the pump beam, a Ti:sapphire crystal, and an output coupler. The Ti:sapphire laser may comprise a frequency multiplying element arranged to receive output coupler radiation from the output coupler having a center wavelength of about 760 nm and with wavelength tuning range up to 960 nm and for multiplying (e.g. doubling or tripling) a frequency of the output coupler radiation to produce the illuminating laser radiation at a predetermined center wavelength in a tuning range of about 250 nm to 450 nm (e.g., about 380 nm). The frequency multiplying element may comprise a nonlinear optical element which may comprise a lithium triborate crystal.

Illuminating a portion of a target material supply path with the illuminating laser radiation having a center wavelength less than 400 nm may be performed in part using a fiber beam delivery system for conveying the illuminating laser radiation from the light source to the portion of the target material supply path. The fiber beam delivery system may comprise a multiorder fiber.

The illuminating radiation may be pulsed with a pulse duration in a range of 1 to 10 nanoseconds. The illuminating radiation may have a line width not less than 4 nm.

Illuminating a portion of a target material supply path with the illuminating laser radiation having a center wavelength less than 400 nm may comprise using an Nd:YAG laser and the illuminating laser radiation may be derived as a harmonic (e.g., a fourth harmonic) of the Nd:YAG laser.

Further embodiments, features, and advantages of the subject matter of the present disclosure, as well as the structure and operation of the various embodiments are described in detail below with reference to accompanying drawings.

### BRIEF DESCRIPTION OF THE DRAWINGS

FIG. 1 is a schematic, not-to-scale, view of an overall broad conception for a laser-produced plasma EUV radiation source.

FIG. 2 is a schematic, not-to-scale view of a target material metrology system for use in a laser-produced plasma EUV radiation source.

FIGS. 3A, 3B, and 3C are diagrams, not-to-scale, illustrating certain conditions of target material a laser-produced plasma EUV radiation source.

FIG. 4 is a diagram, not-to-scale, of an illumination source for a target material metrology system for use in a laser-produced plasma EUV radiation source according to one aspect of an embodiment.

FIG. 5 is a diagram, not-to-scale, of an illumination source for a target material metrology system for use in a laser-produced plasma EUV radiation source according to one aspect of an embodiment.

Further features and advantages of the disclosed subject matter, as well as the structure and operation of various embodiments of the disclosed subject matter, are described in detail below with reference to the accompanying drawings. It is noted that the applicability of the disclosed subject matter is not limited to the specific embodiments described herein. Such embodiments are presented herein for illustrative purposes only. Additional embodiments will be apparent to persons skilled in the relevant art based on the teachings contained herein.

### DETAILED DESCRIPTION

Various embodiments are now described with reference to the drawings, wherein like reference numerals are used to refer to like elements throughout. In the following description, for purposes of explanation, numerous specific details are set forth in order to promote a thorough understanding of multiple embodiments. It may be evident in some or all instances, however, that any embodiment described below can be practiced without adopting the specific design details described below.

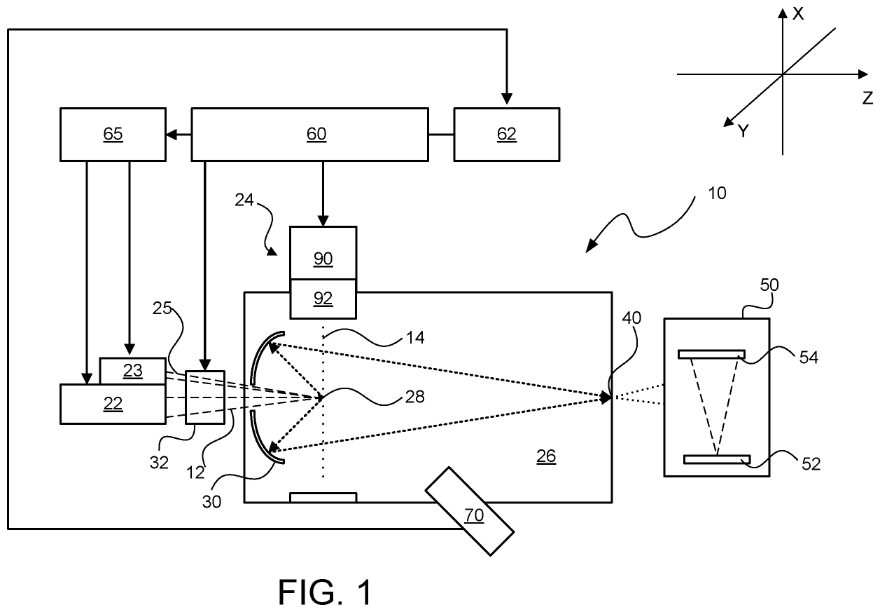

With initial reference to FIG. 1, there is shown a schematic view of an exemplary EUV radiation source, e.g., a laser produced plasma EUV radiation source 10 according to one aspect of an embodiment of the presently disclosed subject matter. As shown, the EUV radiation source 10 may include a pulsed or continuous laser source 22, which may for example be a pulsed gas discharge CO₂ laser source producing a beam 12 of radiation at a wavelength generally below 20 μm, for example, in the range of about 10.6 μm or to about 0.5 μm or less. The pulsed gas discharge CO₂ laser source may have DC or RF excitation operating at high power and at a high pulse repetition rate. The EUV radiation source 10 may also include one or more modules such as conditioning laser 23 emitting a beam 25 of conditioning radiation as explained above.

The EUV radiation source 10 also includes a target delivery system 24 for delivering target material in the form of liquid droplets or a continuous liquid stream. In this example, the target material is a liquid, but it could also, for example, be a solid. The target material may be made up of tin or a tin compound, although other materials could be used. In the system depicted the target material delivery system 24 introduces targets 14 of the target material into the interior of a vacuum chamber 26 to an irradiation region 28 where the target material may be irradiated to produce plasma. In some cases, an electrical charge is placed on the target material to permit the target material to be steered toward or away from the irradiation region 28. It should be noted that as used herein an irradiation region is a region where target material irradiation is to occur and is an irradiation region even at times when no irradiation is actually occurring. The EUV light source may also include a beam focusing and steering system 32.

In the system shown, the components are arranged so that the targets 14 travel substantially horizontally along a target material supply path. The direction from the laser source 22 towards the irradiation region 28, that is, the nominal direction of propagation of the beam 12, may be taken as the Z axis. The path the targets 14 take from the target material delivery system 24 to the irradiation region 28 may be taken as the X axis and the targets travel in the −X direction. The view of FIG. 1 is thus normal to the XZ plane. Also, while a system in which the targets 14 travel substantially horizontally is depicted, it will be understood by one having ordinary skill in the art the other arrangements can be used in which the targets travel vertically or at some angle with respect to gravity between and including 90 degrees (horizontal) and 0 degrees (vertical).

The EUV radiation source 10 may also include an EUV light source controller system 60, which may also include a laser firing control system 65, along with the laser beam steering system 32. The EUV radiation source 10 may also include a detector such as a target position detection system which may include one or more target imagers 70 that generate an output indicative of the absolute or relative position of a target droplet, e.g., relative to the irradiation region 28, and provide this output to a target position detection feedback system 62.

The target position detection feedback system 62 may use the output of the target imager 70 to compute a target position and trajectory, from which a target error can be computed. The target error can be computed on a target-by-target basis, or as an average, or on some other basis. The target error may then be provided as an input to the light source controller 60. In response, the light source controller 60 can generate a control signal such as a laser position, direction, or timing correction signal and provide this control signal to the laser beam steering system 32. The laser beam steering system 32 can use the control signal to change the location and/or focal power of the laser beam focal spot within the chamber 26. The laser beam steering system 32 can also use the control signal to change the geometry of the interaction of the beam 12 and the target 14. For example, the beam 12 can be made to strike the target 14 off-center or at an angle of incidence other than directly head-on.

As shown in FIG. 1, the target material delivery system 24 may include a target delivery control system 90. The target delivery control system 90 is operable in response to a signal, for example, the target error described above, or some quantity derived from the target error provided by the light source controller 60, to adjust paths of the target targets 14 through the irradiation region 28. This may be accomplished, for example, by repositioning the point at which a target delivery mechanism 92 releases the target targets 14. The target release point may be repositioned, for example, by tilting the target delivery mechanism 92 or by shifting (e.g., laterally translating) the target delivery mechanism 92. The target delivery mechanism 92 extends into the chamber 26 and is preferably externally supplied with target material and gas from a gas source (not shown) to place the target material in the target delivery mechanism 92 under pressure.

Continuing with FIG. 1, the EUV radiation source 10 may also include one or more optical elements. In the following discussion, a collector 30 is used as an example of such an optical element, but the discussion applies to other optical elements as well. The collector 30 may be a normal incidence reflector, for example, implemented as a multilayer mirror (MLM) fabricated by depositing many pairs of Mo and Si layers on a substrate with additional thin barrier layers, for example B₄C, ZrC, Si₃N₄ or C, deposited at each interface to effectively block thermally-induced interlayer diffusion. The collector 30 may be in the form of a prolate ellipsoid, with a central aperture to allow the beam 12 to pass through and reach the irradiation region 28. The collector 30 may be, e.g., in the shape of an ellipsoid that has a first focus at the irradiation region 28 and a second focus at a so-called intermediate point 40 (also called the intermediate focus 40) where the EUV radiation may be output from the EUV radiation source 10 and input to, e.g., an integrated circuit lithography scanner or stepper 50 which uses the radiation, for example, to process a silicon wafer workpiece 52 in a known manner using a reticle or mask 54. The silicon wafer workpiece 52 is then additionally processed in a known manner to obtain an integrated circuit device.

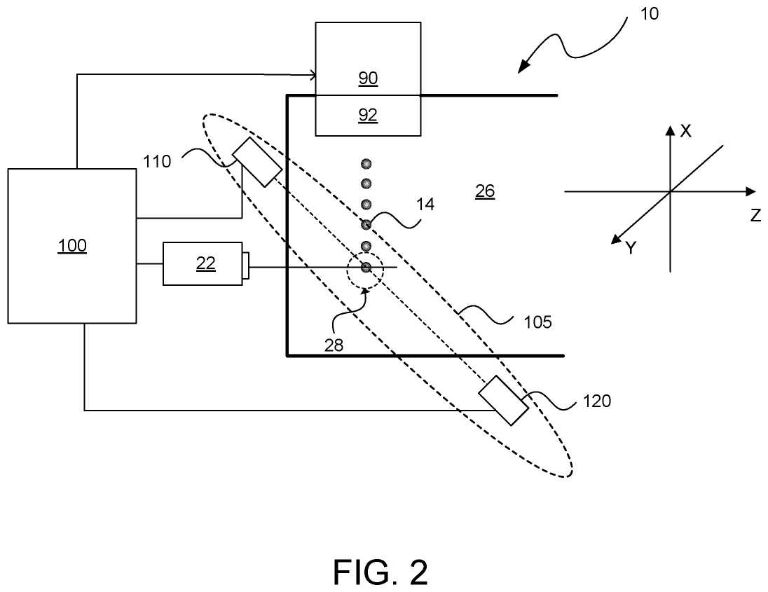

FIG. 2 is a diagram, not to scale, of a portion of the EUV radiation source 10 showing the laser source 22, targets 14, the irradiation region 28, the chamber 26, the target delivery control system 90, and the target delivery mechanism 92. Elements such as the collector 30 shown in FIG. 1 are not shown in FIG. 2 in order to promote clarity. The arrangement of FIG. 2 also includes a controller 100 combining, for example, the functions of the light source controller 60, target position detection feedback system 62, and the laser firing control system 65 of FIG. 1. The arrangement diagrammed in FIG. 2 also includes a target material metrology system 105 including an illumination source 110 and an illumination receiver 120. The arrangement shown is for backlit or bright field imaging in which the target is lit from behind with respect to the radiation receiver 120. For this reason the illumination source 110 may also be referred to as a backlit module (BLM). One of ordinary skill will appreciate that the target material metrology system 105 could be configured as a front lit or darkfield system in which the target is lit from in front and the illumination receiver receives radiation that has been reflected by the target.

As used herein, the term “imaging” and its cognates refers to obtaining a camera image as well as to obtaining a shadowgram, to obtaining a shadowgraph, and to simply detecting the presence and contours of an object in a field of view, i.e., detection. Thus, depending on the application, the illumination receiver 110 may be implemented as a camera, a CCD array, and so on, and corresponds to target imager 70 of FIG. 1.

As one example, a conventional illumination source may produce radiation with a wavelength at 905 nm for target metrology. Such an illumination module is configured for target metrology in which the target is in the form of a liquid droplet. For this reason also the receiving module is designated as a target formation camera (DFC). The system is designed to image targets made of liquid tin with a density of about 6.9 g/cm³, which gives a number density of about 3.5×10²² Sn atoms/cm³. The resolution limit of such a system is on the order of a few microns when implemented with practical optical arrangements in the EUV source.

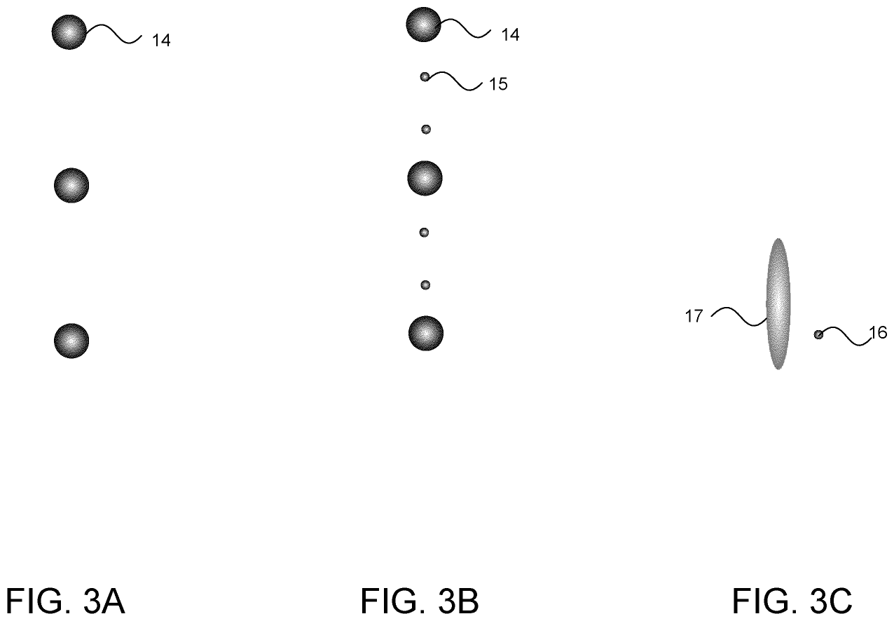

One challenge presented by the use of such an arrangement arises from the existence of so-called “satellite” droplets. The target material leaving the droplet generator is initially in the form of a continuous stream. This continuous stream breaks up into a stream of very small microdroplets shortly after leaving the droplet generator nozzle. Then the microdroplets in the droplet/target stream coalesce as they travel towards the irradiation region until they become fully coalesced after traveling a distance referred to as the coalescence length. This is the state of the targets 14 in FIG. 3A.

While ideally all of the microdroplets coalesce into fully coalesced targets travelling the desired trajectory with the desired spacing, there may be some microdroplets that do not. These microdroplets that remain in the stream even after the coalescence length are referred to as satellite droplets. These are shown as microdroplets 15 in FIG. 3B. Their characteristics such as number and frequency can give an indication of system performance such as droplet generator health and are also useful in the process of optimizing the performance of the droplet generator (droplet generator tuning). For this reason it may be beneficial to detect the presence of such droplets. Thus, while a resolution limit of a few microns is in general sufficient to permit detection of fully coalesced target, detection of satellite droplets from incomplete coalescence requires a resolution limit of not greater than 1 μm.

Also, the rarefication pulse may result in smaller globules 16 of target material ejecting from the target 17 resulting in smaller target material masses as shown in FIG. 3C, the detection of which also requires greater resolution.

In addition, the disk-like distribution 17 as shown in FIG. 3C may include portions (for example, a thinned central portion) may be too rarefied (not sufficiently dense) to be perceived by a conventional target material metrology system. The density of the target material is selected primarily to optimize the conversion of the target material to create a plasma. A CO₂ laser with wavelength at 10.59 μm functions optimally with a Sn density below about 1×10¹⁸ Sn atoms/cm² ( 1/10000 of the density of liquid Sn,) which gives a plasma density near the critical density. As mentioned, the optimal target material density may be achieved by conditioning the target with a pedestal pulse that, among other things, redistributes the mass of the target into a disk-like shape having a middle portion with the desired density. It is difficult if not impossible, however, to detect and/or image, for example, tin at this density using conventional target material metrology light sources. It thus may be additionally beneficial if the illumination source were also capable of producing radiation at a wavelength that makes it possible to “see” low density target material.

For the strong emission lines, absorption by the target material is proportional to emission intensity, i.e., a higher emission intensity gives a higher absorption. This trend means that higher absorption can be expected at shorter wavelengths. For a conventional illumination source producing a 905 nm backlight, the relative intensity is 30, but light having a wavelength less than 400 nm produces absorption as much as two orders of magnitude above absorption for 905 nm.

In essence, rarefied tin target material is more opaque to radiation at a wavelength less than about 400 nm. Thus, radiation at a wavelength less than about 400 nm may be used to detect and/or image rarified tin targets.

The description herein is in terms of denominated wavelengths for the purpose of having specific examples to facilitate the description. One of ordinary skill in the art will appreciate, however, that other wavelengths may be used as long as those wavelengths satisfy the criterion of being sufficiently absorbed by rarefied target material that the rarefied target material can be imaged, e.g., detected.

In addition, using radiation with a narrow linewidth, typically the full width at half-maximum (FWHM) of its optical spectrum, leads to a noisy background due to spikes and rings resulting from the use of coherent radiation. This noisy background also limits resolution.

Thus, in general, it is desirable to use an illumination source that produces radiation having a shorter wavelength and broader linewidth. At the same time, there is also a need to use an illumination source that can generate radiation in very short pulses that can “freeze” the motion of a target that is travelling at 100 m/s.

There is accordingly a need for light sources that are able to detect and/or image a target material such as tin at the densities that are best suited for conversion. In accordance with one aspect of an embodiment, this need is addressed by the use of an illumination source having a wavelength below 400 nm, i.e., in the upper part of the UV wavelength range of 100-400 nm. As one example, the illumination source may include a Ti:sapphire laser. More specifically, as one example, the 380 nm second harmonic of a Ti:sapphire laser may be used to image the rarefied low density Sn target. Such a light source may be configured to a have a broad line width of about 4 nm. Here and elsewhere, “about” when applied to a value is intended to refer to a range including that value and other values within customary tolerances of that value.

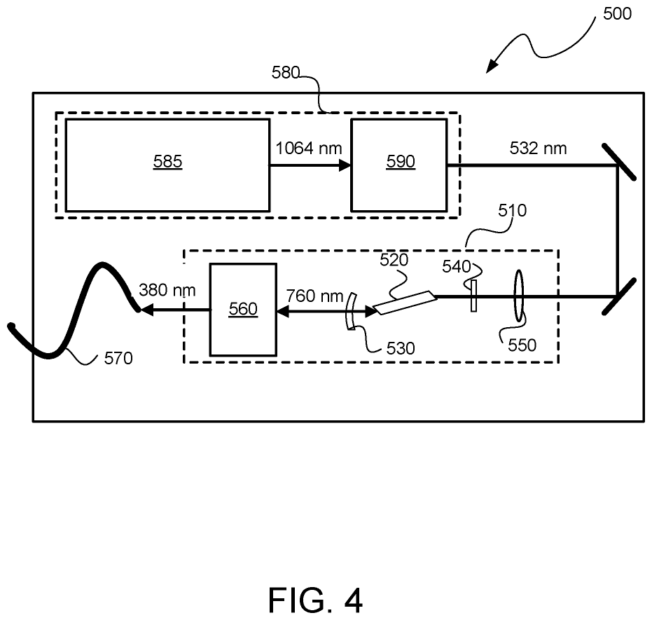

FIG. 4 is a diagram of one embodiment of an illumination source 500 for producing radiation having the desired characteristics. In the arrangement of FIG. 4, a Ti:sapphire laser 510 (also known as a Ti:Al₂O₃ laser, a titanium-sapphire laser, or a Ti:sapph) is pumped at 532 nm with a (DPSS) diode-pumped solid-state laser 585, which in this example may be a frequency-multiplied neodymium-doped yttrium aluminum garnet (Nd:YAG) laser, where 532 nm represents the second harmonic of the fundamental 1064 nm radiation emitted by neodymium-doped lasing material.

The Ti:sapphire laser 510 includes a Ti:sapphire crystal 520 with each of its ends in the direction of the beam (i.e., the end through which the beam enters the crystal and the end through which the beam leaves the crystal) cut at Brewster's angle to minimize reflection losses. For laser beam propagation from air to laser crystal (with refractive index n), Brewster's angle θ_{B} is defined as θ_{B}=arctan(n). The index of refraction n for Ti:Sapphire is about 1.76, resulting in a Brewster's angle of about 60.4°.

The Ti:sapphire laser 510 also includes an output coupler 530 having a reflectivity of 60% to 80% at 760 nm and a dichroic optical element 540 with high reflectivity at 760 nm and antireflection coatings for 532 nm. The Ti:sapphire laser 510 also includes a focusing lens 550. The Ti:sapphire laser 510 may be operated with a gain-switching scheme, i.e., to emit laser radiation with a wavelength tuning range up to 960 nm, e.g., about 760 nm when the gain is above the threshold for oscillation but no output when the gain drops below the threshold for oscillation.

The frequency of the 760 nm radiation, tunable from about 720 nm to about 960 nm produced by the Ti:sapphire crystal 520 is multiplied by a frequency multiplier 560, e.g., doubled to produce 380 nm radiation. The frequency multiplier 560 may be part of the Ti:sapphire laser 510 as shown or may be positioned outside of the Ti:sapphire laser 510. The frequency multiplier 560 may be implemented as a nonlinear optical crystal such as a lithium triborate (LiB₃O₅ or LBO) crystal used for second harmonic generation (SHG). SHG, also called frequency doubling, is a nonlinear optical process in which two photons with the same frequency interact with a nonlinear material, are “combined,” and generate a new photon with twice the energy of the initial photons (equivalently, twice the frequency and half the wavelength). With a wavelength tuning range from about 720 nm to 960 nm, and SHG and third harmonic generation (THG), UV radiation with a wavelength in the range from about 250 nm to 450 nm can be generated.

As shown, the output of the frequency multiplier 560 is coupled into a fiber beam delivery system 570. Beam homogenization can be realized by using a multiple order fiber in the fiber beam delivery system 570, resulting in overlap of multiple beam modes with broad linewidths and, hence, less coherence.

As mentioned, in the arrangement shown in FIG. 4, the Ti:sapphire laser 510 is pumped by 532 nm pulses produced by a DPSS laser 580 which may be implemented, for example, as a frequency-doubled Nd:YAG laser 585. The 532 nm wavelength of these pulses is the SHG of the 1064 nm fundamental of the Nd:YAG lasing material. A frequency multiplier 590 may also be implemented as a nonlinear optical crystal such as beta barium borate ((β-BaB₂O₄ or BBO) for SHG.

The pulse duration of the Ti:sapphire laser 510 depends on the pulse duration of the pumping laser pulse applied to it. With a pumping laser duration of several nanoseconds, the pulse duration of the Ti:Sapphire laser will also be several nanoseconds. Its center wavelength and linewidth depend largely on the 760 nm coating of the output coupler 530. The linewidth at 380 nm can be greater than 4 nm, which is 100 times broader than that of the fourth harmonic at 266 nm. This broader linewidth makes it possible to renders satellite droplets visible wherever they appear in the field of view.

The submicron resolution made possible with this arrangement is useful to measure targets with diameters in the range of 20-27 μm as well as submicron satellite droplets. Information obtained from these measurements can be used to calculate Sn volume balance, i.e., how much Sn is in each target, which is useful for on-line droplet generator tuning and droplet generator qualification, both of which can improve droplet generator lifetime.

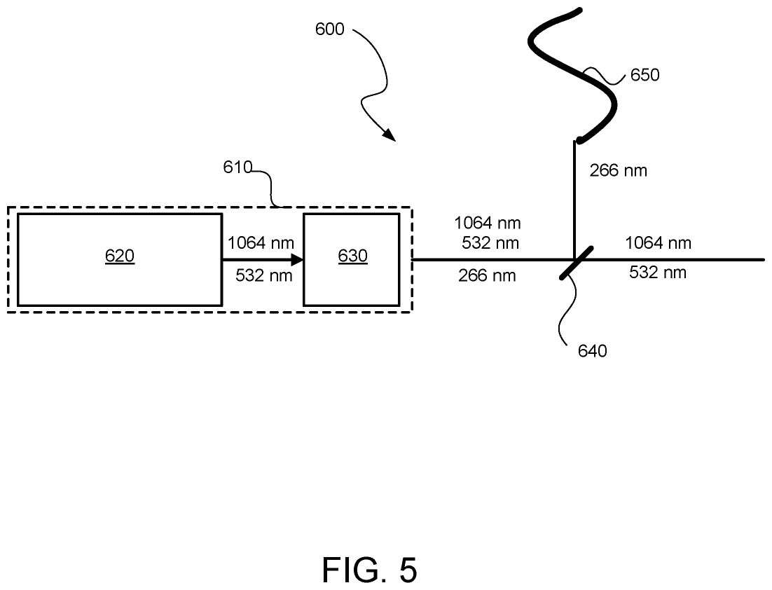

FIG. 5 is a diagram of another arrangement for generation target material metrology radiation having a wavelength less than 400 nm according to another aspect of an embodiment. As shown in FIG. 5, the output of a Q-switched Nd:YAG laser source 620 at 532 nm (SHG of the 1064 nm fundamental wavelength of an Nd:YAG laser) is directed to a frequency multiplier 630 which may be implemented as a BBO nonlinear crystal to generate fourth harmonic laser radiation at 266 nm. A mirror 640 separates the laser radiation at 266 nm from the emitted radiation at other wavelengths. For example, the mirror 640 may have a high reflection efficiency at 266 nm and a high transmission efficiency at 532 nm and 1064 nm. As shown, the 266 nm output of the frequency multiplier 630 is coupled into a fiber beam delivery system 650. Beam homogenization can be realized by using a multiple order fiber, resulting in overlap of multiple beam modes with broad linewidths and, hence, less coherence.

The present disclosure is made with the aid of functional building blocks illustrating the implementation of specified functions and relationships between the functional building blocks. The boundaries of these functional building blocks have been arbitrarily defined herein for the convenience of the description. Alternate boundaries can be defined so long as the specified functions are appropriately performed. For example, control module functions can be divided among several systems or performed at least in part by an overall control system.

The above description includes examples of one or more embodiments. It is, of course, not possible to describe every conceivable combination of components or methodologies for purposes of describing the aforementioned embodiments, but one of ordinary skill in the art will recognize that many further combinations and permutations of various embodiments are possible. Accordingly, the described embodiments are intended to embrace all such alterations, modifications, and variations that fall within the spirit and scope of the appended claims.

Furthermore, to the extent that the term “includes” is used in either the detailed description or the claims, such term is intended to be inclusive in a manner similar to the term “comprising” as “comprising” is construed when employed as a transitional word in a claim. Furthermore, although elements of the described aspects and/or embodiments may be described or claimed in the singular, the plural is contemplated unless limitation to the singular is explicitly stated. Additionally, all or a portion of any aspect and/or embodiment may be utilized with all or a portion of any other aspect and/or embodiment, unless stated otherwise.

The embodiments can be further described using the following clauses:

1. A target metrology system for an extreme ultraviolet light source, the target metrology system comprising:
a light source arranged to emit illuminating laser radiation at a center wavelength less than 400 nm and to illuminate a portion of a target material supply path with the illuminating laser radiation; and a radiation receiver arranged to receive the illuminating laser radiation after the illuminating laser radiation has illuminated the portion of the target material supply path.
   2. The target metrology system of clause 1 wherein the radiation receiver produces an output signal indicative of a position of a target in the portion of the target material supply path.
   3. The target metrology system of clause 2 further comprising a position detection feedback system arranged to receive the output signal of the radiation receiver and adapted to compute at least one of a target position and a target trajectory based at least in part on the output signal.
   4. The target metrology system of clause 1 wherein the radiation receiver comprises a target imager.
   5. The target metrology system of clause 4 wherein the target imager comprises a camera.
   6. The target metrology system of clause 4 wherein the target imager comprises a CCD array.
   7. The target metrology system of clause 4 wherein the target imager produces a shadowgraph.
   8. The target metrology system of clause 1 wherein the light source is adapted to produce the illuminating laser radiation to have a center wavelength of about 266 nm.
   9. The target metrology system of clause 1 wherein the light source comprises a frequency-multiplied Ti:sapphire laser arranged to receive a pump beam and to emit the illuminating laser radiation at a center wavelength in a range from about 250 nm to about 450 nm.
   10. The target metrology system of clause 1 wherein the light source comprises a frequency-multiplied Ti:sapphire laser arranged to receive a pump beam and to emit illuminating laser radiation at a center wavelength of about 380 nm.
   11. The target metrology system of clause 1 wherein the light source further includes a diode pumped solid state (DPSS) laser arranged to produce the pump beam, the pump beam having a center wavelength of about 532 nm.
   12. The target metrology system of clause 11 wherein the DPSS laser includes an Nd:YAG laser and a frequency multiplier arranged to receive the beam and for producing the pump beam.
   13. The target metrology system of clause 9 wherein the Ti:sapphire laser comprises a dichroic optical element arranged to receive the pump beam, a Ti:sapphire crystal, and an output coupler.
   14. The target metrology system of clause 9 wherein the Ti:sapphire laser comprises a frequency multiplying element arranged to receive output coupler radiation from the output coupler having a center wavelength of about 760 nm and for multiplying a frequency of the output coupler radiation to produce the illuminating laser radiation at a center wavelength of about 380 nm and with wavelength tuning range from 250 nm to 450 nm.
   15. The target metrology system of clause 14 wherein the frequency multiplying element comprises a nonlinear optical element.
   16. The target metrology system of clause 15 wherein the nonlinear optical element comprises a lithium triborate crystal.
   17. The target metrology system of clause 1 further comprising a fiber beam delivery system arranged and adapted to convey the illuminating laser radiation from the light source to the portion of the target material supply path.
   18. The target metrology system of clause 17 wherein the fiber beam delivery system comprises a multiorder fiber.
   19. The target metrology system of clause 1 wherein the light source is adapted to produce the illuminating laser radiation to have a pulse duration in a range of 1 to 10 nanoseconds.
   20. The target metrology system of clause 1 wherein the light source is adapted to produce the illuminating laser radiation having a line width not less than 4 nm.
   21. The target metrology system of clause 1 wherein the light source comprises an Nd:YAG laser and the illuminating laser radiation is derived as a harmonic of the Nd:YAG laser.
   22. A target metrology method for an extreme ultraviolet light source, the target metrology method comprising:
illuminating a portion of a target material supply path with the illuminating laser radiation having a center wavelength less than 400 nm;
receiving as received illumination the illuminating laser radiation after the illuminating laser radiation has illuminated the portion of the target material supply path; and
imaging target material present in the portion of the target material supply path on the basis of the received illumination.
   23. The target metrology method of clause 22 wherein imaging target material comprises producing an output signal indicative of a position of the target material present in the portion of the target material supply path.
   24. The target metrology method of clause 23 further comprising computing at least one of a target position or a target trajectory based at least in part on the output signal.
   25. The target metrology method of clause 22 wherein imaging target material comprises using a target imager.
   26. The target metrology method of clause 25 wherein the target imager comprises a camera.
   27. The target metrology method of clause 25 wherein the target imager comprises a CCD array.
   28. The target metrology method of clause 22 wherein imaging target material comprises producing a shadowgraph.
   29. The target metrology method of clause 22 wherein the illuminating laser radiation has a center wavelength of about 266 nm.
   30. The target metrology method of clause 22 wherein illuminating a portion of a target material supply path with the illuminating laser radiation having a center wavelength less than 400 nm is performed in part by using a frequency-multiplied Ti:sapphire laser arranged to receive a pump beam and to emit illuminating laser radiation at a center wavelength of about 380 nm.
   31. The target metrology method of clause 30 further comprising pumping the Ti:sapphire laser with a diode pumped solid state (DPSS) laser arranged to produce the pump beam, the pump beam having a center wavelength of about 532 nm.
   32. The target metrology method of clause 31 wherein the DPSS laser includes an Nd:YAG laser and a frequency multiplier arranged to receive the beam and for producing the pump beam.
   33. The target metrology method of clause 30 wherein the Ti:sapphire laser comprises a dichroic optical element arranged to receive the pump beam, a Ti:sapphire crystal, and an output coupler.
   34. The target metrology method of clause 30 wherein the Ti:sapphire laser comprises a frequency multiplying element arranged to receive output coupler radiation from the output coupler having a center wavelength of about 760 nm and for multiplying a frequency of the output coupler radiation to produce the illuminating laser radiation at a center wavelength of about 380 nm.
   35. The target metrology method of clause 34 wherein the frequency multiplying element comprises a nonlinear optical element.
   36. The target metrology method of clause 35 wherein the nonlinear optical element comprises a lithium triborate crystal.
   37. The target metrology method of clause 22 further wherein illuminating a portion of a target material supply path with the illuminating laser radiation having a center wavelength less than 400 nm is performed at least in part using a fiber beam delivery system for conveying the illuminating laser radiation from the light source to the portion of the target material supply path.
   38. The target metrology method of clause 37 wherein the fiber beam delivery system comprises a multiorder fiber.
   39. The target metrology method of clause 22 wherein the illuminating laser radiation is pulsed with a pulse duration in a range of 1 to 10 nanoseconds.
   40. The target metrology method of clause 22 wherein the illuminating laser radiation has a line width not less than 4 nm.
   41. The target metrology method of clause 22 wherein illuminating a portion of a target material supply path with the illuminating laser radiation having a center wavelength less than 400 nm comprises using an Nd:YAG laser and the illuminating laser radiation is derived as a harmonic of the Nd:YAG laser.

The above described implementations and other implementations are within the scope of the following claims.

1. A target metrology system for an extreme ultraviolet light source, the target metrology system comprising:
a light source arranged to emit illuminating laser radiation at a center wavelength less than 400 nm and to illuminate a portion of a target material supply path with the illuminating laser radiation; and
a radiation receiver arranged to receive the illuminating laser radiation after the illuminating laser radiation has illuminated the portion of the target material supply path.

2. The target metrology system of claim 1 wherein the radiation receiver produces an output signal indicative of a position of a target in the portion of the target material supply path.

3. The target metrology system of claim 2 further comprising a position detection feedback system arranged to receive the output signal of the radiation receiver and adapted to compute at least one of a target position and a target trajectory based at least in part on the output signal.

4. The target metrology system of claim 1 wherein the radiation receiver comprises a target imager and the target imager comprises one or more of: a camera or a CCD array.

5. (canceled)

6. (canceled)

7. The target metrology system of claim 4 wherein the target imager produces a shadowgraph.

8. The target metrology system of claim 1 wherein the light source is adapted to produce the illuminating laser radiation to have a center wavelength of about 266 nm.

9. The target metrology system of claim 1 wherein the light source comprises a frequency-multiplied Ti:sapphire laser arranged to receive a pump beam and to emit the illuminating laser radiation at a center wavelength in a range from about 250 nm to about 450 nm.

10. The target metrology system of claim 1 wherein the light source comprises a frequency-multiplied Ti:sapphire laser arranged to receive a pump beam and to emit illuminating laser radiation at a center wavelength of about 380 nm.

11. The target metrology system of claim 1 wherein the light source further includes a diode pumped solid state (DPSS) laser arranged to produce the pump beam, the pump beam having a center wavelength of about 532 nm.

12. The target metrology system of claim 11 wherein the DPSS laser includes an Nd:YAG laser and a frequency multiplier arranged to receive the beam and for producing the pump beam.

13. The target metrology system of claim 9 wherein the Ti:sapphire laser comprises a dichroic optical element arranged to receive the pump beam, a Ti:sapphire crystal, and an output coupler.

14. The target metrology system of claim 9 wherein the Ti:sapphire laser comprises a frequency multiplying element arranged to receive output coupler radiation from the output coupler having a center wavelength of about 760 nm and for multiplying a frequency of the output coupler radiation to produce the illuminating laser radiation at a center wavelength of about 380 nm and with wavelength tuning range from 250 nm to 450 nm.

15. The target metrology system of claim 14 wherein the frequency multiplying element comprises a nonlinear optical element and wherein the nonlinear optical element comprises a lithium triborate crystal.

16. (canceled)

17. The target metrology system of claim 1 further comprising a fiber beam delivery system arranged and adapted to convey the illuminating laser radiation from the light source to the portion of the target material supply path.

18. (canceled)

19. The target metrology system of claim 1 wherein the light source is adapted to produce the illuminating laser radiation to have a pulse duration in a range of 1 to 10 nanoseconds.

20. The target metrology system of claim 1 wherein the light source is adapted to produce the illuminating laser radiation having a line width not less than 4 nm.

21. The target metrology system of claim 1 wherein the light source comprises an Nd:YAG laser and the illuminating laser radiation is derived as a harmonic of the Nd:YAG laser.

22. A target metrology method for an extreme ultraviolet light source, the target metrology method comprising:
illuminating a portion of a target material supply path with the illuminating laser radiation having a center wavelength less than 400 nm;
receiving as received illumination the illuminating laser radiation after the illuminating laser radiation has illuminated the portion of the target material supply path; and
imaging target material present in the portion of the target material supply path on the basis of the received illumination.

23. The target metrology method of claim 22 wherein imaging target material comprises producing an output signal indicative of a position of the target material present in the portion of the target material supply path.

24. The target metrology method of claim 23 further comprising computing at least one of a target position or a target trajectory based at least in part on the output signal.

25. The target metrology method of claim 22 wherein imaging target material comprises using a target imager.

26. (canceled)

27. (canceled)

28. (canceled)

29. (canceled)

30. (canceled)

31. (canceled)

32. (canceled)

33. (canceled)

34. (canceled)

35. (canceled)

36. (canceled)

37. The target metrology method of claim 22 further wherein illuminating a portion of a target material supply path with the illuminating laser radiation having a center wavelength less than 400 nm is performed at least in part using a fiber beam delivery system for conveying the illuminating laser radiation from the light source to the portion of the target material supply path.

38. (canceled)

39. (canceled)

40. (canceled)

41. (canceled)
